(19) United States
(12) Patent Application Publication
(10) Pub. No.: US 2014/0261668 A1
(43) Pub. Date: Sep. 18, 2014

(54) GROWTH OF CIGS THIN FILMS ON FLEXIBLE GLASS SUBSTRATES

(71) Applicants: Jason D. Myers, Alexandria, VA (US); Jesse A. Frantz, Landover, MD (US); Robel Y. Bekele, Washington, DC (US); Jasbinder S. Sanghera, Ashburn, VA (US)

(72) Inventors: Jason D. Myers, Alexandria, VA (US); Jesse A. Frantz, Landover, MD (US); Robel Y. Bekele, Washington, DC (US); Jasbinder S. Sanghera, Ashburn, VA (US)

(73) Assignee: The Government of the United States of America, as represented by the Secretary of the Navy, Washington, DC (US)

(21) Appl. No.: 14/211,010

(22) Filed: Mar. 14, 2014

Related U.S. Application Data
(60) Provisional application No. 61/787,383, filed on Mar. 15, 2013.

(51) Int. Cl. H01L 31/0216; H01L 31/18

(52) U.S. Cl. CPC H01L 31/02167; H01L 31/1828; H01L 31/18
USPC 136/256; 438/95; 204/192.25

(57) ABSTRACT

An article made by: sputtering molybdenum onto a flexible glass substrate, and depositing a photovoltaic material on the molybdenum by sputtering, thermal evaporation, multi-target ternary or binary sputtering, or nanoparticle techniques.

This application claims the benefit of U.S. Provisional Application No. 61/787,383, filed on Mar. 15, 2013. The provisional application is incorporated herein by reference.

### TECHNICAL FIELD

The present disclosure is generally related to photovoltaic thin films.

### DESCRIPTION OF RELATED ART

CIGS (Cu(In₁₋ₓ,Gaₓ)Se₂) has been established as the leading material for thin film photovoltaics (PVs), with record laboratory power conversion efficiencies of ˜20% (Repins et al., “19.9%-efficient ZnO/CdS/CuInGaSe₂ solar cell with 81.2% fill factor” Progress in Photovoltaics: Research and Applications 16 235-239 (2008)). Much lighter than traditional silicon-based photovoltaics, it is an attractive option for portable power generation. With a total deposited thickness of less than 5 μtm the vast majority of the weight of a CIGS device is in the substrate material. In the laboratory, this is typically 1-2 mm thick soda-lime glass (SLG) for convenience. In commercial applications, rigid glass or metal foils are used as substrate materials but there is a constant push for lighter alternatives. Modules based on lighter substrates are less expensive to transport and deploy and require a simpler support structure, reducing installation expense. In addition to reduced weight, flexibility is a desired quality in an ideal substrate, as a flexible substrate is more rugged than a rigid counterpart and integrates readily in a variety of applications, such as unmanned aerial vehicles (UAVs) and wearable PV, such as solar blankets.

Unfortunately, lighter and flexible alternatives have been flawed compared to the lab-standard SLG substrate. Stainless steel foils, though flexible, are heavy, rough, and require barrier layers to prevent diffusion of iron into the CIGS film during growth. Polymer materials are lightweight and extremely flexible but cannot handle the high processing temperatures required for highly efficient CIGS (>550° C.).

### BRIEF SUMMARY

Disclosed herein is a method comprising: sputtering molybdenum onto a flexible glass substrate, and depositing a photovoltaic material on the molybdenum by sputtering, thermal evaporation, multi-target ternary or binary sputtering, or nanoparticle techniques.

Also disclosed herein is an article made by the above method.

### BRIEF DESCRIPTION OF THE DRAWINGS

A more complete appreciation of the invention will be readily obtained by reference to the following Description of the Example Embodiments and the accompanying drawings.

FIG. 1 shows a flexed CORNING® WILLOW® glass substrate with an array of molybdenum contacts. The inset shows completed devices on one of the bottom contact pads. Polymer tabs are around the edges for handling purposes. Device efficiency was 3.5%.

FIG. 2 shows initial device results on flexible glass.

### DETAILED DESCRIPTION OF EXAMPLE EMBODIMENTS

In the following description, for purposes of explanation and not limitation, specific details are set forth in order to provide a thorough understanding of the present disclosure. However, it will be apparent to one skilled in the art that the present subject matter may be practiced in other embodiments that depart from these specific details. In other instances, detailed descriptions of well-known methods and devices are omitted so as to not obscure the present disclosure with unnecessary detail.

Disclosed is a method of processing Cu(In₁₋ₓGaₓ)Se₂, (0≦x≦1) (CIGS) and other photovoltaic materials on a flexible glass substrate to obtain lightweight, high-performance, and flexible photovoltaic (PV) devices. A commercially available flexible glass, for example CORNING® WILLOW® glass, may be used as a flexible substrate for CIGS and processed flexible devices (FIG. 1) at temperatures far exceeding those for polymer substrates without any additional barrier layers. Early device efficiencies are ˜3.5% (FIG. 2) with expected efficiencies upon optimization comparable to or greater than those on SLG, or ˜20% or greater. Table 1 summarizes the weight and area of 100 W modules made on different substrate materials including WILLOW® glass.

TABLE 1
Estimated weight and area of 100 W CIGS modules on various substrates.
Efficiencies are assumed using the highest published module values,
with Willow Glass efficiencies assumed to be equivalent to soda lime glass.

| | | | | area of 100 W | weight of | fraction of |
|---|---|---|---|---|---|---|
| | thickness | density | module | module | 100 W | SLG module |
| substrate | (cm) | (g/cm³) | efficiency (%) | (cm²) | module (kg) | weight |
| soda lime glass | 0.1 | 2.5 | 15.7 | 6369 | 1.592 | 1 |
| stainless steel | 0.01 | 8 | 15.5 | 6452 | 0.516 | 0.32 |
| polyimide | 0.01 | 1.42 | 14 | 7143 | 0.101 | 0.06 |
| WILLOW ® glass | 0.01 | 2.5 | 15.7 | 6369 | 0.159 | 0.10 |

Potential advantages of the article include, but are not limited to:
1) The material may be lighter than traditional soda lime glass based modules.
2) The material may allow for a greater range of processing temperatures than other substrate materials without any need for additional diffusion barrier layers.
3) The material may be better for film deposition and growth than CIGS on polymer substrates due to reduced roughness of WILLOW® glass.
4) The flexibility of the substrate may allow for new applications, such as a solar blanket or UAV integration with higher efficiencies than polymer substrates can achieve.

Any thin flexible glass, including but not limited to WILLOW® glass may be used as a substrate. The glass may be in form of individual sheets or a roll-to-roll process can be used. Optionally, the glass may first be cleaned in subsequent solutions of surfactant, deionized water, acetone, and isopropanol. Molybdenum may be deposited one or both sides of the substrate, as long as the photovoltaic material is deposited on the Mo. An alternative to Mo can also be used on one or both sides of the substrate. Other photovoltaic materials can be used instead of CIGS, including but not limited to CZTS (Cu₂ZnSn(S,Se)₄). The photovoltaic material can be deposited using any vacuum or non-vacuum based technology, such as thermal evaporation, multi-target ternary/binary sputtering, nanoparticle techniques, and electrodeposition.

After deposition of the photovoltaic material the substrate and photovoltaic material may be etched in a KCN solution. Then CdS or an alternative, including but not limited to ZnS, In₂S₃ and their mixtures, can be deposited on the photovoltaic material. The CdS or alternative may be deposited by any means, including but not limited to chemical bath and sputtering.

Next zinc oxide or aluminum doped zinc oxide may be sputtered on the CdS or alternative, followed by depositing a Ni/Al collecting grid thereon. Additional annealing and post processing (i.e. selenization) steps can be performed on the CIGS films at temperatures up to and exceeding 550° C.

The following example is given to illustrate specific applications. The example is not intended to limit the scope of the disclosure in this application.

### EXAMPLE

A 100 mm×100 mm sheet of 100 μm-thick WILLOW® glass was cleaned in subsequent solutions of surfactant, deionized water, acetone, and isopropanol. A layer of molybdenum (˜1 μm) was then sputtered on each side of the sheet, and then CIGS was sputtered at a substrate temperature of 550-700° C. at a power of 100-300 W. After CIGS deposition, the substrate was removed from the vacuum chamber and etched in KCN solution. Then, CdS was deposited using chemical bath deposition and the substrate was placed back in a vacuum chamber for sputtering of a ZnO/AZO (aluminum doped zinc oxide) transparent cathode. Finally, Ni/Al collecting grids were deposited through a shadow mask. The efficiency of this preliminary device was 3.5%.

Obviously, many modifications and variations are possible in light of the above teachings. It is therefore to be understood that the claimed subject matter may be practiced otherwise than as specifically described. Any reference to claim elements in the singular, e.g., using the articles “a,” “an,” “the,” or “said” is not construed as limiting the element to the singular.

What is claimed is:

1. A method comprising:
sputtering molybdenum onto a flexible glass substrate; and
depositing a photovoltaic material on the molybdenum by sputtering, thermal evaporation, multi-target ternary or binary sputtering, or nanoparticle techniques.

2. The method of claim 1;
wherein the photovoltaic material is Cu(In₁₋ₓGaₓ)Se₂;
wherein 0≦x≦1.

3. The method of claim 1, wherein the photovoltaic material is Cu₂ZnSn(S,Se)₄.

4. The method of claim 1, wherein the photovoltaic material is deposited by sputtering.

5. The method of claim 1, further comprising:
cleaning the substrate in subsequent solutions of surfactant, deionized water, acetone, and isopropanol before sputtering molybdenum.

6. The method of claim 1, further comprising:
etching the substrate and photovoltaic material in a KCN solution.

7. The method of claim 1, further comprising:
depositing CdS on the photovoltaic material.

8. The method of claim 1, further comprising:
depositing CdS, ZnS, In₂S₃, or a mixture thereof on the photovoltaic material.

9. The method of claim 7, further comprising:
sputtering zinc oxide and aluminum doped zinc oxide on the CdS, ZnS, In₂S₃, or mixture thereof.

10. The method of claim 9, further comprising:
depositing a Ni/Al collecting grid on the zinc oxide and aluminum doped zinc oxide.

11. An article made by a method comprising:
sputtering molybdenum onto a flexible glass substrate; and
depositing a photovoltaic material on the molybdenum by sputtering, thermal evaporation, multi-target ternary or binary sputtering, or nanoparticle techniques.

12. The article of claim 11;
wherein the photovoltaic material is Cu(In₁₋ₓGaₓ)Se₂;
wherein 0≦x≦1.

13. The article of claim 11, wherein the photovoltaic material is Cu₂ZnSn(S,Se)₄.

14. The article of claim 11, wherein the photovoltaic material is deposited by sputtering.

15. The article of claim 11, wherein the method further comprises:
cleaning the substrate in subsequent solutions of surfactant, deionized water, acetone, and isopropanol before sputtering molybdenum.

16. The article of claim 11, wherein the method further comprises:
etching the substrate and photovoltaic material in a KCN solution.

17. The article of claim 11, wherein the method further comprises:
depositing CdS on the photovoltaic material.

18. The article of claim 11, wherein the method further comprises:
depositing CdS, ZnS, In₂S₃, or a mixture thereof on the photovoltaic material.

19. The article of claim 17, wherein the method further comprises:
sputtering zinc oxide and aluminum doped zinc oxide on the CdS, ZnS, In₂S₃, or mixture thereof.

20. The article of claim 19, wherein the method further comprises:
depositing a Ni/Al collecting grid on the zinc oxide and aluminum doped zinc oxide.
